(19) United States
(12) Patent Application Publication
(10) Pub. No.: US 2015/0373833 A1
(43) Pub. Date: Dec. 24, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Yong Ho BAEK, Suwon-Si (KR); Hyo Seung Nam, Suwon-Si (KR); Jae Hoon Choi, Suwon-Si (KR); Eung Suek Lee, Suwon-Si (KR); Jeong Ho Lee, Suwon-Si (KR)

(73) Assignee: SAMSUNG ELECTRO-MECHANICS CO., LTD., Suwon-Si (KR)

(21) Appl. No.: 14/488,225

(22) Filed: Sep. 16, 2014

(30) Foreign Application Priority Data
Jun. 23, 2014 (KR) 10-2014-0076662

(51) Int. Cl. H05K 1/02; H05K 3/46

(52) U.S. Cl. CPC H05K 1/0213; H05K 3/4644

(57) ABSTRACT

There are provided a printed circuit board and a method of manufacturing the same. According to an exemplary embodiment of the present disclosure, a printed circuit board includes: an insulating layer; a first outer layer circuit pattern formed in a lower portion of the insulating layer to be embedded in the insulating layer; and a second outer layer circuit pattern formed on the insulating layer to protrude from the insulating layer.

### CROSS-REFERENCE TO RELATED APPLICATION

This application claims the foreign priority benefit of Korean Patent Application No. 10-2014-007662, filed on Jun. 23, 2014, entitled “Printed Circuit Board And Method Of Manufacturing The Same” which is hereby incorporated by reference in its entirety into this application.

### BACKGROUND

Embodiments of the present disclosure relate to a printed circuit board and a method of manufacturing the same.

With the rapid development of a semiconductor technology, a semiconductor device is remarkably growing. A semiconductor package in which electronic devices such as a semiconductor device are mounted on a printed circuit board has been developed.

With the miniaturization and high integration of the semiconductor device, the number of input and output pads of the semiconductor device is increased and the size of the input and output pads is miniaturized. The size of the input and output pads between the semiconductors devices and the printed circuit board on which the semiconductor devices are mounted may be different. To cope with the above problem, an interposer substrate is additionally inserted between the semiconductor device and the printed circuit board. The interposer substrate includes a via having a through type structure and includes a multilayered wiring structure for redistributing an input and an output of the semiconductor device.

### RELATED ART DOCUMENT

### Patent Document

(Patent Document 1) U.S. Pat. No. 6,861,288

### SUMMARY

An aspect of the present disclosure may provide a printed circuit board capable of implementing circuit patterns having different pitches and a method of manufacturing the same.

Another aspect of the present disclosure may provide a printed circuit board which may be directly connected to external components and a method of manufacturing the same.

According to an aspect of the present disclosure, a printed circuit board may include: an insulating layer; a first outer layer circuit pattern formed in a lower portion of the insulating layer to be embedded in the insulating layer; and a second outer layer circuit pattern formed on the insulating layer to protrude from the insulating layer.

The insulating layer may be formed in a multilayer and at least one of the multilayered insulating layers may be made of an insulating material which does not include filler.

The insulating layer embedding the first outer layer circuit pattern among the multilayered insulating layers may be made of an insulating material which does not include filler.

The insulating layer provided with the second outer layer circuit pattern among the multilayered insulating layers may be made of an insulating material which does not include filler.

According to another aspect of the present disclosure, a method of manufacturing a printed circuit board may include: preparing a carrier substrate; forming a first outer layer circuit pattern on the carrier substrate; forming an insulating layer on the carrier substrate to embed the first outer layer circuit pattern; forming a second outer layer circuit pattern on the insulating layer; and removing the carrier substrate.

The forming of the insulating layer may include: forming a first insulating layer on the carrier substrate to embed the first outer layer circuit pattern; and forming a second insulating layer on the first insulating layer.

In the forming of the insulating layer, at least one of the first insulating layer and the second insulating layer may be made of an insulating material which does not include filler.

In the preparing of the carrier substrate, a carrier metal layer and a barrier metal layer may be stacked on a carrier core and the carrier substrate having the barrier metal layer formed at an outermost layer thereof may be prepared.

The barrier metal layer may be made of a material which does not react to an etchant removing the carrier metal layer.

The barrier metal layer may be made of titanium (Ti) or nickel (Ni).

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified view illustrating a printed circuit board according to an exemplary embodiment of the present disclosure; and

FIGS. 2 through 18 are exemplified views illustrating a method of manufacturing a printed circuit board according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

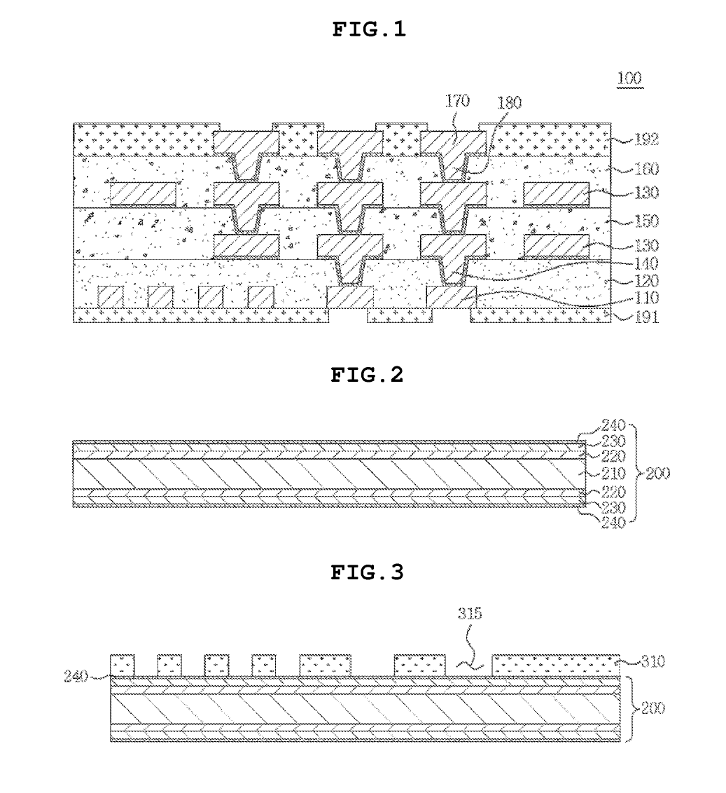

FIG. 1 is an exemplified view illustrating a printed circuit board according to an exemplary embodiment of the present disclosure.

Referring to FIG. 1, a printed circuit board 100 according to the exemplary embodiment of the present disclosure includes a first insulating layer 120, a second insulating layer 160, a first outer layer circuit pattern 110, an inner layer circuit pattern 130, an inner layer insulating layer 150, a first via 140, a second via 180, a second outer layer circuit pattern 170, a first passivation layer 191, and a second passivation layer 192.

According to the exemplary embodiment of the present disclosure, the first insulating layer 120 is an insulating layer made of an insulating material which does not include filler. Here, the insulating material is an insulating material used for interlayer insulation in a circuit board field. According to the exemplary embodiment of the present disclosure, the first insulating layer 120 is made of the insulating material which does not include the filler and therefore an upper surface thereof has high flatness. For example, the first insulating layer 120 may be made of a photo imagable dielectric (PID).

According to the exemplary embodiment of the present disclosure, the first outer layer circuit pattern 110 is formed in a lower portion of the first insulating layer 120. Further, the first outer layer circuit pattern 110 is embedded in the first insulating layer 120 and a lower surface thereof is exposed to an outside of the first insulating layer 120. According to the exemplary embodiment of the present disclosure, the first outer layer circuit pattern 110 is made of a conductive material which is used in the circuit board field. For example, the first outer layer circuit pattern 110 may be made of copper.

According to the exemplary embodiment of the present disclosure, the first outer layer circuit pattern 110 is a fine pattern having a fine pitch. According to the exemplary embodiment of the present disclosure, the first outer layer circuit pattern 110 is formed in the first insulating layer 120 made of the insulating material which does not include the filler, and thus may be formed in the fine pattern.

According to the exemplary embodiment of the present disclosure, the inner layer circuit pattern 130 is formed on the first insulating layer 120. According to the exemplary embodiment of the present disclosure, the inner layer circuit pattern 130 is made of the conductive material such as copper which is used in the circuit board field.

According to the exemplary embodiment of the present disclosure, the first via 140 is formed in the first insulating layer 120. Further, according to the exemplary embodiment of the present disclosure, the first via 140 has an upper surface bonded to the inner layer circuit pattern 130 and a lower surface bonded to the first outer layer circuit pattern 110, such that the inner layer circuit pattern 130 is electrically connected to the first outer layer circuit pattern 110. According to the exemplary embodiment of the present disclosure, the first via 140 is made of the conductive material such as copper which is used in the circuit board field.

According to the exemplary embodiment of the present disclosure, the first via 140 is a fine pattern having a fine pitch and a fine diameter. According to the exemplary embodiment of the present disclosure, the first via 140 is formed on the first insulating layer 120 like the first outer layer circuit pattern 110 and thus may be formed in the fine pattern.

According to the exemplary embodiment of the present disclosure, the inner layer insulating layer 150 is formed on the first insulating layer 120. According to the exemplary embodiment of the present disclosure, the inner layer insulating layer 150 is made of a composite polymer resin which is generally used as an interlayer insulating material in the circuit board field. For example, the inner layer insulating layer 150 may be made of an epoxy based resin, such as prepreg, ajinomoto build up film (ABF), FR-4, bismaleimide triazine (BT), and the like. However, according to the exemplary embodiment of the present disclosure, a material forming the inner layer insulating layer 150 is not limited thereto and may be selected from the insulating materials known in the circuit board field.

According to the exemplary embodiment of the present disclosure, the inner layer circuit pattern 130 is a fine pattern having a fine pitch. According to the exemplary embodiment of the present disclosure, the inner layer circuit pattern 130 may be formed in the fine pattern by being made of the insulating material which does not include the filler and thus being formed on the first insulating layer 120 having the high flatness.

According to the exemplary embodiment of the present disclosure, the inner layer circuit pattern 130 and the inner layer insulating layer 150 are formed in a multilayer, but are not limited thereto. The inner layer circuit pattern 130 may be formed in a single layer and when the inner layer circuit pattern 130 is formed in the single layer, the inner layer insulating layer 150 may be omitted. According to the exemplary embodiment of the present disclosure, the second insulating layer 160 is formed on the inner layer insulating layer 150 to embed the inner layer circuit pattern 130. When the inner layer circuit pattern 130 is formed in the single layer, the second insulating layer 160 is formed over the first insulating layer 120. According to the exemplary embodiment of the present disclosure, the second insulating layer 160 is made of the composite polymer resin which is generally used as the interlayer insulating material in the circuit board field. For example, the second insulating layer 160 may be made of an epoxy based resin, such as prepreg, ajinomoto build up film (ABF), FR-4, bismaleimide triazine (BT), and the like. However, according to the exemplary embodiment of the present disclosure, the material forming the second insulating layer 160 is not limited thereto and may be selected from the insulating materials known in the circuit board field.

According to the exemplary embodiment of the present disclosure, the second outer layer circuit pattern 170 is formed on the second insulating layer 160. Further, the second outer layer circuit pattern 170 is formed to have a structure protruding from an upper surface of the second insulating layer 160. According to the exemplary embodiment of the present disclosure, the second outer layer circuit pattern 170 is made of the conductive material such as copper which is used in the circuit board field.

According to the exemplary embodiment of the present disclosure, the second outer layer circuit pattern 170 is formed to have a pitch larger than that of the first outer layer circuit pattern 110.

According to the exemplary embodiment of the present disclosure, the second via 180 is formed in the second insulating layer 160. Further, according to the exemplary embodiment of the present disclosure, the second via 180 has an upper surface bonded to the second outer layer circuit pattern 170 and a lower surface bonded to the inner layer circuit pattern 130, such that the second outer layer circuit pattern 170 is electrically connected to the inner layer circuit pattern 130. According to the exemplary embodiment of the present disclosure, the second via 180 is made of the conductive material such as copper which is used in the circuit board field.

According to the exemplary embodiment of the present disclosure, a lower portion of the printed circuit board 100 is provided with a fine pattern and an upper portion thereof is provided with a circuit pattern having a pitch larger than that of the lower portion thereof. That is, the printed circuit board 100 is simultaneously provided with the circuit patterns having different pitches. This may directly connect the printed circuit board 100 having the circuit patterns having different pitches to the external components without the interposer.

The exemplary embodiment of the present disclosure describes, by way of example, that the first insulating layer 120 is made of the insulating material which does not include the filler, but is not limited thereto. That is, according to another exemplary embodiment of the present disclosure, when the second outer layer circuit pattern 170 is formed in a fine pattern, the second insulating layer 160 may be made of the insulating material which does not include the filler. As such, in the printed circuit board 100 according to the exemplary embodiment of the present disclosure, the layer on which the fine pattern is formed among the first insulating layer 120 and the second insulating layer 160 is made of the insulating material which does not include the filler.

Further, when the fine pattern needs to be formed in the inner layer insulating layer 150, the corresponding inner layer insulating layer 150 may be made of the insulating material which does not include the filler.

According to the exemplary embodiment of the present disclosure, the first passivation layer 191 is formed beneath the first insulating layer 120 and the first outer layer circuit pattern 110 to protect the first outer layer circuit pattern 110. Further, according to the exemplary embodiment of the present disclosure, the first passivation layer 191 is formed to partially expose the first outer layer circuit pattern 110 to the outside. Here, the first outer layer circuit pattern 110 exposed to the outside may be an area which is electrically connected to the external components. For example, the external components may be a substrate, a package, electronic components, and the like.

According to the exemplary embodiment of the present disclosure, the second passivation layer 192 is formed on the second insulating layer 160 and the second outer layer circuit pattern 170 to protect the second outer layer circuit pattern 170 from the outside. Further, the second passivation layer 192 is formed to partially expose the second outer layer circuit pattern 170 to the outside. Here, the second outer layer circuit pattern 170 exposed to the outside may be an area which is electrically connected to the external components.

According to the exemplary embodiment of the present disclosure, the first passivation layer 191 and the second passivation layer 192 are made of a solder resist.

Further, although not illustrated, surfaces of the first outer layer circuit pattern 110 and the second outer layer circuit pattern 170 which are exposed by the first passivation layer 191 and the second passivation layer 192 may be further provided with a surface treating layer.

FIGS. 2 through 18 are exemplified views illustrating a method of manufacturing a printed circuit board according to an exemplary embodiment of the present disclosure.

Referring to FIG. 2, a carrier substrate 200 is provided.

According to the exemplary embodiment of the present disclosure, the carrier substrate 200 includes a carrier core 210, a first carrier metal layer 220, a second carrier metal layer 230, and a barrier metal layer 240.

According to the exemplary embodiment of the present disclosure, the carrier core 210 may be made of an insulating material or a metal material.

According to the exemplary embodiment of the present disclosure, the first carrier metal layer 220 is formed on the carrier core 210. Further, according to the exemplary embodiment of the present disclosure, the second carrier metal layer 230 is formed on the first carrier metal layer 220. According to the exemplary embodiment of the present disclosure, the first carrier metal layer 220 and the second carrier metal layer 230 are separated from each other later. According to the exemplary embodiment of the present disclosure, although not illustrated, a release layer may be further formed between the first carrier metal layer 220 and the second carrier metal layer 230 for effective separation. According to the exemplary embodiment of the present disclosure, the first carrier metal layer 220 and the second carrier metal layer 230 are made of copper. However, the material of the first carrier metal layer 220 and the second carrier metal layer 230 is not limited to copper and therefore other metal materials may be used.

Further, according to the exemplary embodiment of the present disclosure, the barrier metal layer 240 is formed on the second carrier metal layer 230 and becomes an outermost layer of the carrier substrate 200. According to the exemplary embodiment of the present disclosure, the barrier metal layer 240 protects the printed circuit board (not illustrated) formed on the carrier substrate 200 from an etchant when the second carrier metal layer 230 is removed. Therefore, the barrier metal layer 240 is made of a material different from that of the second carrier metal layer 230 and is made of a material which does not react to the etchant removing the second carrier metal layer 230. For example, the barrier metal layer 240 is made of nickel (Ni) or titanium (Ti).

According to the exemplary embodiment of the present disclosure, the barrier metal layer 240 is formed thinly by a sputter method or an electroplating method. Further, when the barrier metal layer 240 is formed by the sputter method, the barrier metal layer 240 has high flatness.

Referring to FIG. 3, a first plating resist 310 is formed on the carrier substrate 200.

According to the exemplary embodiment of the present disclosure, the first plating resist 310 is formed on the barrier metal layer 240. Further, the first plating resist 310 includes a first opening 315 through which the barrier metal layer 240 of the area in which the first outer layer circuit pattern (not illustrated) is formed is exposed.

According to the exemplary embodiment of the present disclosure, the first plating resist 310 is formed by being applied on the carrier substrate 200 in a liquid form. The first plating resist 310 is formed by being applied in the liquid form and thus uniformity of a thickness is increased. Next, the first opening 315 is formed by performing exposure and development. According to the exemplary embodiment of the present disclosure, the first plating resist 310 has the high uniformity and thus the first outer layer circuit pattern (not illustrated) is easily implemented as a fine circuit.

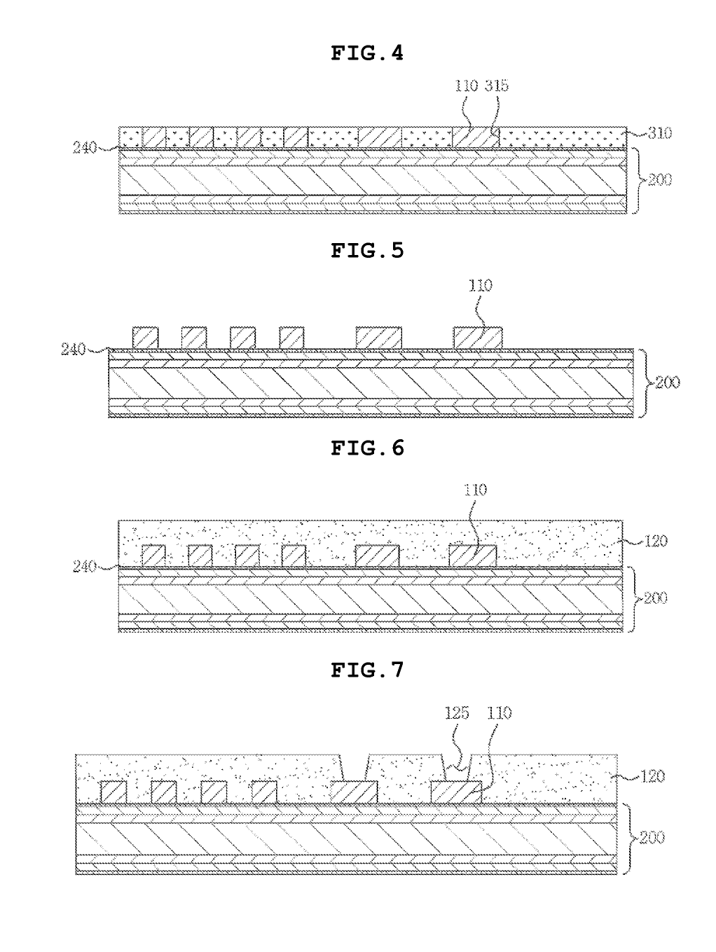

Referring to FIG. 4, the first outer layer circuit pattern 110 is formed.

According to the exemplary embodiment of the present disclosure, the first outer layer circuit pattern 110 is a fine pattern having a fine pitch.

According to the exemplary embodiment of the present disclosure, the first outer layer circuit pattern 110 is formed by performing the electroplating on the first opening 315 of the first plating resist 310. In this case, the barrier metal layer 240 exposed by the first opening 315 becomes a seed layer for the electroplating.

According to the exemplary embodiment of the present disclosure, when the barrier metal layer 240 is formed by the sputter method, the barrier metal layer 240 has the high flatness. Therefore, the fine pattern of the first outer layer circuit pattern 110 is easily implemented.

According to the exemplary embodiment of the present disclosure, the first outer layer circuit pattern 110 is made of the conductive material. In this case, the first outer layer circuit pattern 110 is made of a different material from the barrier metal layer 240. Further, the first outer layer circuit pattern 110 is made of a material which does not react to the etchant removing the barrier metal layer 240 later. For example, the first outer layer circuit pattern 110 may be made of copper (Cu).

Referring to FIG. 5, the first plating resist 310 (FIG. 4) is removed.

FIG. 6, the first insulating layer 120 is formed.

According to the exemplary embodiment of the present disclosure, the first insulating layer 120 is formed on the carrier substrate 200 to embed the first outer layer circuit pattern 110.

According to the exemplary embodiment of the present disclosure, the first insulating layer 120 is made of the insulating material which does not include the filler. As described above, the first insulating layer 120 is formed on the barrier metal layer 240 having the high flatness and is made of the insulating material which does not include the filler and therefore the upper surface thereof has the high flatness. For example, the first insulating layer 120 may be made of the photo imagable dielectric (PID).

According to the exemplary embodiment of the present disclosure, the first insulating layer 120 is formed by being applied on the carrier substrate 200 in a liquid form.

Referring to FIG. 7, a first via hole 125 is formed.

According to the exemplary embodiment of the present disclosure, the first via hole 125 is formed to penetrate through the first insulating layer 120 to partially expose the first outer layer circuit pattern 110.

According to the exemplary embodiment of the present disclosure, the first via hole 125 is formed by performing exposure and development.

According to the exemplary embodiment of the present disclosure, the first via hole 125 is formed by performing exposure and development on the insulating material which does not include the filler and therefore the via hole having a fine pitch and a fine diameter is easily formed.

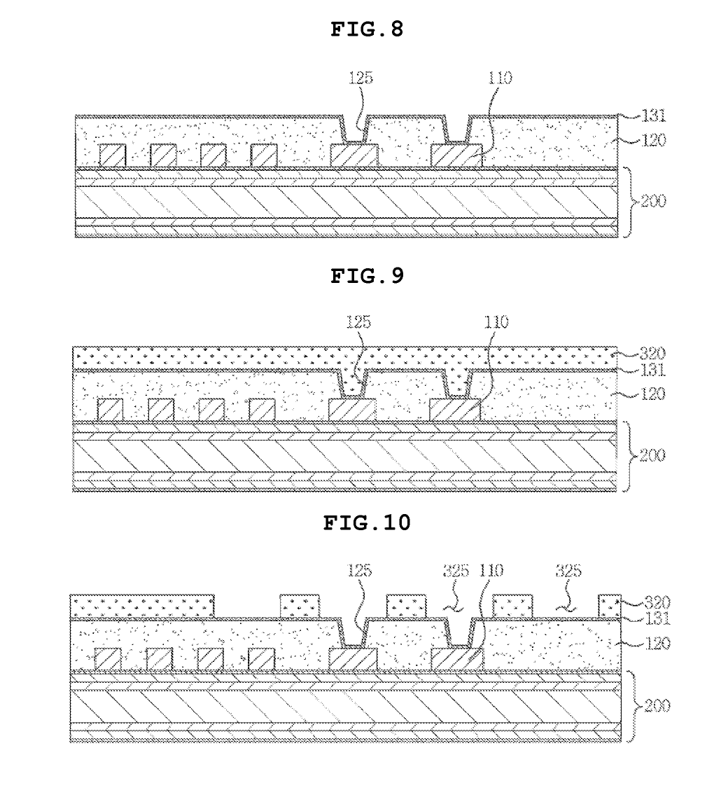

Referring to FIG. 8, the first seed layer 131 is formed.

According to the exemplary embodiment of the present disclosure, the first seed layer 131 is formed on the first insulating layer 120 and on an inner wall of the first via hole 125.

According to the exemplary embodiment of the present disclosure, the first seed layer 131 is formed by the electroless plating method or the sputter method. Further, according to the exemplary embodiment of the present disclosure, the first seed layer 131 is made of the conductive material which is used in the circuit board field. For example, the first seed layer 131 is made of copper.

Referring to FIG. 9, a second plating resist 320 is formed.

According to the exemplary embodiment of the present disclosure, the second plating resist 320 is applied on the first seed layer 131 in a liquid form. According to the exemplary embodiment of the present disclosure, the second plating resist 320 has the liquid form and therefore is applied on the first seed layer 131 and fills inside the first vial hole 125. Further, the second plating resist 320 has the liquid form and therefore is formed to have a uniform thickness.

According to the exemplary embodiment of the present disclosure, the second plating resist 320 is formed in the liquid form but is not limited thereto. For example, the second plating resist 320 may be stacked on the first seed layer 131 in a film form.

Further, according to the exemplary embodiment of the present disclosure, the second plating resist 320 is made of a photosensitive material.

Referring to FIG. 10, the second plating resist 320 may be subjected to patterning.

According to the exemplary embodiment of the present disclosure, the second plating resist 320 is subjected to exposure and development process to form a second opening 325. Here, the second opening 325 is formed to expose the first seed layer 131 of an area in which the second outer layer circuit pattern (not illustrated) is formed.

According to the exemplary embodiment of the present disclosure, the second plating resist 320 is formed on the flat first insulating layer 120 and the first seed layer 131 and has a uniform thickness and therefore the second opening 325 may be formed to have a fine interval or space.

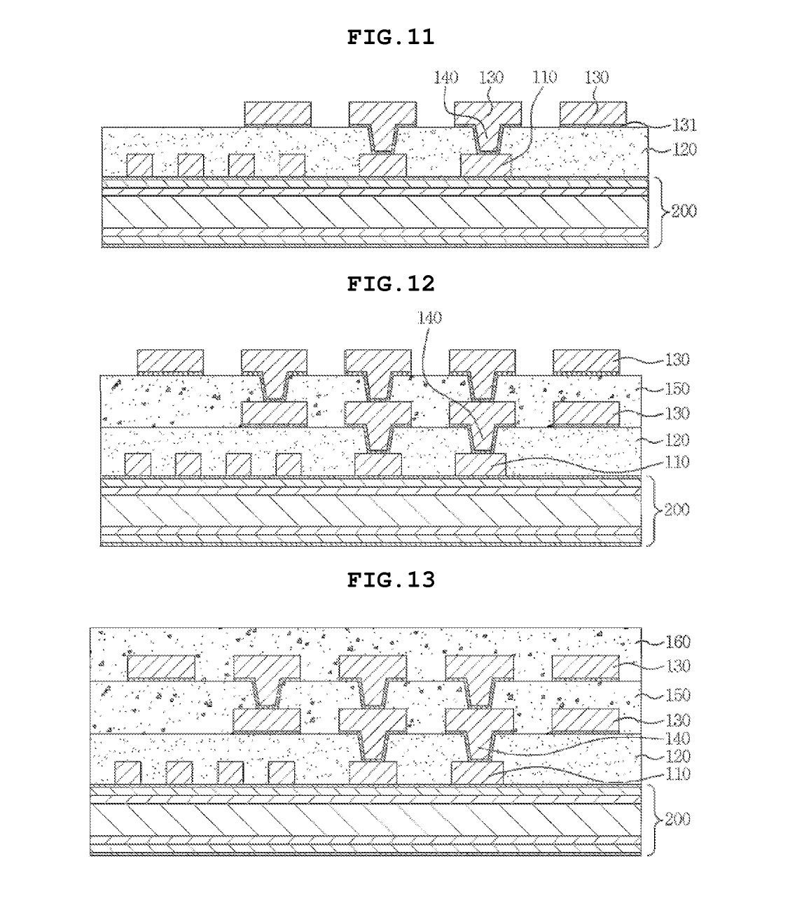

Referring to FIG. 11, the inner layer circuit pattern 130 and the first via 140 are formed.

According to the exemplary embodiment of the present disclosure, the first seed layer 131 exposed to the second opening 325 is subjected to the electroplating. By performing the plating, the inside of the first via hole 125 and the inside of the second opening 325 are filled with the conductive material. Here, any conductive material which is known in the circuit board field may be used. For example, the conductive material may be copper.

The first seed layer 131 exposed to the outside is subjected to the electroplating to form the inner layer circuit pattern 130 including the first seed layer 131 and the first via 140.

According to the exemplary embodiment of the present disclosure, the electroplating is performed and then the second plating resist (FIG. 11) is removed. Further, the second plating resist (FIG. 11) is removed and then the first seed layer 131 exposed to the outside is removed.

By the process, the inner layer circuit pattern 130 and the first via 140 which are illustrated in FIG. 11 are formed. According to the exemplary embodiment of the present disclosure, the inner layer circuit pattern 130 is formed on the flat first insulating layer 120 and therefore may be easily subjected to the fine pattern. Further, according to the exemplary embodiment of the present disclosure, the first via 140 is also formed in the first via hole 125 and therefore has a fine pitch and a fine diameter.

Referring to FIG. 12, the inner layer insulating layer 150 is formed.

According to the exemplary embodiment of the present disclosure, the inner layer insulating layer 150 is formed on the first insulating layer 120 to embed the inner layer circuit pattern 130. According to the exemplary embodiment of the present disclosure, the inner layer insulating layer 150 is made of a composite polymer resin which is generally used as an interlayer insulating material in the circuit board field. For example, the inner layer insulating layer 150 may be made of an epoxy based resin, such as prepreg, ajinomoto build up film (ABF), FR-4, bismaleimide triazine (BT), and the like. However, according to the exemplary embodiment of the present disclosure, a material forming the inner layer insulating layer 150 is not limited thereto and may be selected from the insulating materials known in the circuit board field. When the inner layer circuit pattern 130 is formed in the fine pattern, the inner layer insulating layer 150 may be made of the insulating material which does not include the filler.

According to the exemplary embodiment of the present disclosure, the inner layer insulating layer 150 is formed and then the inner layer circuit pattern 130 may be further formed. In this case, the inner layer circuit pattern 130 formed on the inner layer insulating layer 150 is formed by performing the process of FIG. 11.

The exemplary embodiment of the present disclosure illustrates and describes that the inner layer insulating layer 150 of one layer and the inner layer circuit pattern 130 of two layers are formed, but is not limited thereto. According to the exemplary embodiment of the present disclosure, those skilled in the art may repeat FIGS. 11 and 12 to form the inner layer circuit pattern 130 and the inner layer insulating layer 150 as many as the desired layer number. Further, according to the exemplary embodiment of the present disclosure, the inner layer circuit pattern 130 may be formed in a single layer. In this case, a process of forming the inner layer insulating layer 150 of FIG. 12 is omitted.

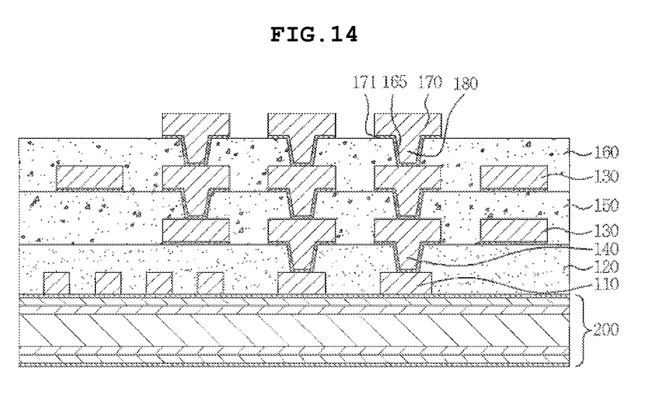

Referring to FIG. 13, the second insulating layer 160 is formed.

According to the exemplary embodiment of the present disclosure, the second insulating layer 160 is formed on the inner layer insulating layer 150 to embed the inner layer circuit pattern 130. When the inner layer circuit pattern 130 is formed in the single layer, the second insulating layer 160 is formed over the first insulating layer 120.

According to the exemplary embodiment of the present disclosure, the second insulating layer 160 is made of the composite polymer resin which is generally used as the interlayer insulating material in the circuit board field. For example, the second insulating layer 160 may be made of an epoxy based resin, such as prepreg, ajinomoto build up film (ABF), FR-4, bismaleimide triazine, and the like (BT). However, according to the exemplary embodiment of the present disclosure, the material forming the second insulating layer 160 is not limited thereto and may be selected from the insulating materials known in the circuit board field.

Referring to FIG. 14, the second outer layer circuit pattern 170 and the second via 180 are formed.

According to the exemplary embodiment of the present disclosure, the second via hole 165 is formed on the second insulating layer 160. Further, a second seed layer 171 is formed on the second insulating layer 160 and on an inner wall of the second via hole 165. Further, the plating resist (not illustrated) provided with an opening through which an area in which the second outer layer circuit pattern 170 and the second via 180 are formed is exposed is formed on the second insulating layer 160. Further, the electroplating is performed and then the plating resist (not illustrated) is removed and the second seed layer 171 exposed to the outside due to the removal of the plating resist (not illustrated) is removed. By the above process, the second circuit pattern 170 and the second via 180 are formed. According to the exemplary embodiment of the present disclosure, the second outer layer circuit pattern 170 is formed to have a structure protruding from the upper surface of the second insulating layer 160. Further, according to the exemplary embodiment of the present disclosure, the second via 180 is formed inside the second insulating layer 160 to electrically connect the inner layer circuit pattern 130 to the second outer layer circuit pattern 170.

According to the exemplary embodiment of the present disclosure, a method for forming the second outer layer circuit pattern 170 and the second via 180 is not limited to the above method, and therefore any method for forming the circuit pattern and the via known in the circuit board field may also be used.

Further, the exemplary embodiment of the present disclosure describes, by way of example, that the first insulating layer 120 is made of the insulating material which does not include the filler, but is not limited thereto. For example, when the second outer layer circuit pattern 170 is formed in a fine pattern, the second insulating layer 160 may be made of the insulating material which does not include the filler. That is, in the printed circuit board 100 according to the exemplary embodiment of the present disclosure, a position of the insulating layer which does not include the filler is changed depending on whether any of the first outer layer circuit pattern 110 and the second outer layer circuit pattern 170 is formed in a fine pattern.

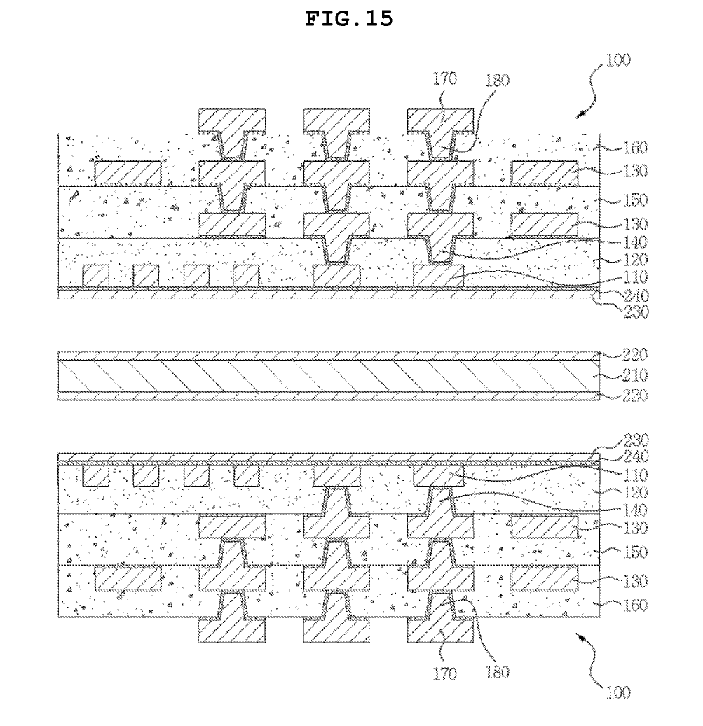

Referring to FIG. 15, the carrier core 210 and the first carrier metal layer 220 are removed.

According to the exemplary embodiment of the present disclosure, the first carrier metal layer 220 is separated from the second carrier metal layer 230 and thus the carrier core 210 and the first carrier metal layer 220 are removed. Further, the second carrier metal layer 230 and the barrier metal layer 240 remain in the state in which they are attached to lower surfaces of the first insulating layer 120 and the first outer layer circuit pattern 110.

FIGS. 2 through 14 illustrate and describe that the printed circuit board 100 is formed on one surface of the carrier substrate 200, but the exemplary embodiment of the present disclosure is not limited thereto. That is, according to the exemplary embodiment of the present disclosure, steps illustrated in FIGS. 2 through 14 are simultaneously performed on both surfaces of the carrier substrate 200 and thus the printed circuit boards 100 are simultaneously formed on both surfaces of the carrier substrate 200. In this case, when the carrier core 210 and the first carrier metal layer 220 are removed, as illustrated in FIG. 15, two printed circuit boards 100 are simultaneously acquired. Next steps may be applied to both the two printed circuit boards 100.

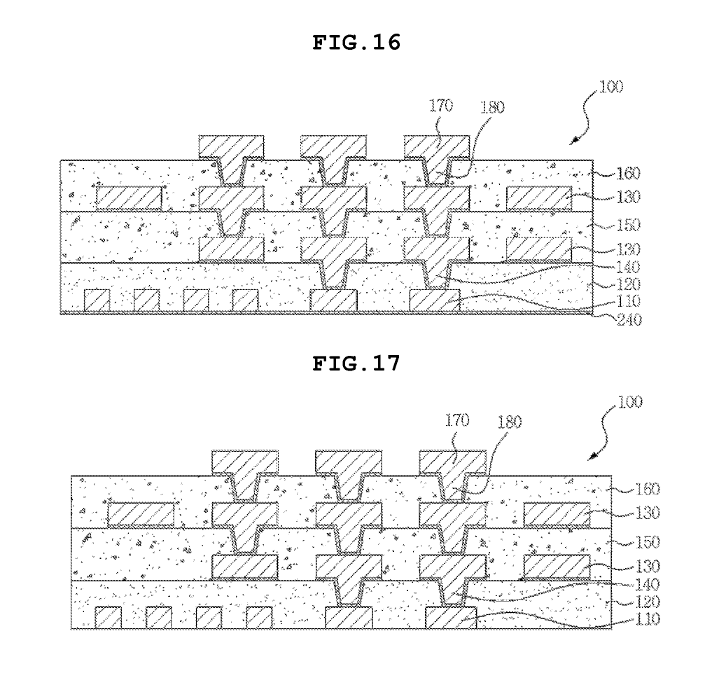

Referring to FIG. 16, the second carrier metal layer 230 (FIG. 15) is removed.

According to the exemplary embodiment of the present disclosure, the second carrier metal layer 230 (FIG. 15) is removed by using the etchant. According to the exemplary embodiment of the present disclosure, the second carrier metal layer 230 (FIG. 15) and the barrier metal layer 240 are made of different materials. Further, the used etchant reacts to the second carrier metal layer 230 (FIG. 15) and does not react to the barrier metal layer 240. Therefore, when the second carrier metal layer 230 (FIG. 15) is removed, the first outer layer circuit pattern 110 is protected from the etchant by the barrier metal layer 240.

Referring to FIG. 17, the barrier metal layer 240 (FIG. 16) is removed.

According to the exemplary embodiment of the present disclosure, the barrier metal layer 240 (FIG. 16) is removed by the etchant. According to the exemplary embodiment of the present disclosure, the barrier metal layer 240 (FIG. 16) and the first outer layer circuit pattern 110 are made of different materials. Further, the used etchant reacts to the barrier metal layer 240 (FIG. 16) and does not react to the first outer layer circuit pattern 110. By using the etchant, only the barrier metal layer 240 (FIG. 16) is removed without the damage of the first outer layer circuit pattern 110.

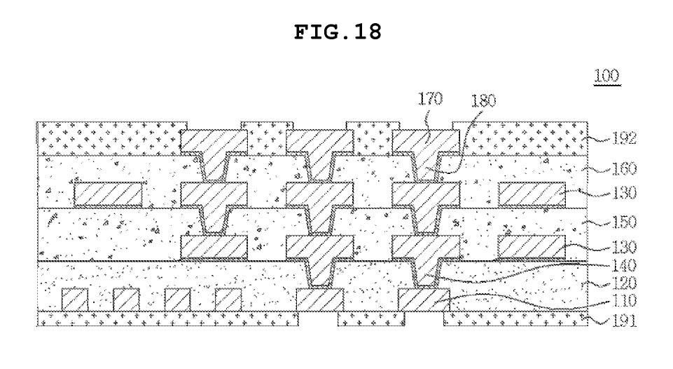

Referring to FIG. 18, the first passivation layer 191 and the second passivation layer 192 are formed.

According to the exemplary embodiment of the present disclosure, the first passivation layer 191 is formed beneath the first insulating layer 120 and the first outer layer circuit pattern 110 to protect the first insulating layer 120 and the first outer layer circuit pattern 110. In this case, the first passivation layer 191 is formed to partially expose the first outer layer circuit pattern 110 to the outside. Here, the first outer layer circuit pattern 110 exposed to the outside may be the area which is electrically connected to the external components. For example, the external components may be a substrate, a package, electronic components, and the like.

According to the exemplary embodiment of the present disclosure, the second passivation layer 192 is formed on the second insulating layer 160 and the second outer layer circuit pattern 170 to protect the second outer layer circuit pattern 170 from the outside. In this case, the second passivation layer 192 is formed to partially expose the second outer layer circuit pattern 170 to the outside. Here, the second outer layer circuit pattern 170 exposed to the outside may be the area which is electrically connected to the external components.

According to the exemplary embodiment of the present disclosure, the first passivation layer 191 and the second passivation layer 192 are made of a solder resist.

Further, although not illustrated, the surfaces of the first outer layer circuit pattern 110 and the second outer layer circuit pattern 170 which are exposed by the first passivation layer 191 and the second passivation layer 192 may be further provided with the surface treating layer.

As such, the printed circuit board 100 according to the exemplary embodiment of the present disclosure of FIG. 1 is formed by the method illustrated in FIGS. 2 through 18. In this case, the method of manufacturing the printed circuit board according to the exemplary embodiment of the present disclosure uses the carrier board 200 having the high flatness to easily form the fine pattern.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board, comprising:
an insulating layer;
a first outer layer circuit pattern formed in a lower portion of the insulating layer to be embedded in the insulating layer; and
a second outer layer circuit pattern formed on the insulating layer to protrude from the insulating layer.

2. The printed circuit board of claim 1, wherein the insulating layer is formed in a multilayer.

3. The printed circuit board of claim 2, wherein at least one of the multilayered insulating layers is made of an insulating material which does not include filler.

4. The printed circuit board of claim 2, wherein the insulating layer embedding the first outer layer circuit pattern among the multilayered insulating layers is made of an insulating material which does not include filler.

5. The printed circuit board of claim 2, wherein the insulating layer provided with the second outer layer circuit pattern among the multilayered insulating layers is made of an insulating material which does not include filler.

6. A printed circuit board, comprising:
a first insulating layer;
a first outer layer circuit pattern formed in a lower portion of the first insulating layer to be embedded in the first insulating layer;
a second insulating layer formed on the first insulating layer; and
a second outer layer circuit pattern formed on the second insulating layer to protrude from the second insulating layer,
wherein at least one of the first insulating layer and the second insulating layer is made of an insulating material which does not include filler.

7. The printed circuit board of claim 6, further comprising:
an inner layer circuit pattern formed on the first insulating layer and formed between the first outer layer circuit pattern and the second outer layer circuit pattern.

8. A method of manufacturing a printed circuit board, the method comprising:
preparing a carrier substrate;
forming a first outer layer circuit pattern on the carrier substrate;
forming an insulating layer on the carrier substrate to embed the first outer layer circuit pattern;
forming a second outer layer circuit pattern on the insulating layer; and
removing the carrier substrate.

9. The method of claim 8, wherein the forming of the insulating layer includes:
forming a first insulating layer on the carrier substrate to embed the first outer circuit pattern; and
forming a second insulating layer on the first insulating layer.

10. The method of claim 9, wherein in the forming of the insulating layer, at least one of the first insulating layer and the second insulating layer is made of an insulating material which does not include filler.

11. The method of claim 9, further comprising:
after the forming of the first insulating layer, forming an inner layer circuit pattern on the first insulating layer.

12. The method of claim 11, further comprising:
after the forming of the inner layer circuit pattern, forming an inner layer insulating layer embedding the inner layer circuit pattern.

13. The method of claim 11, wherein in the forming of the second insulating layer, the second insulating layer is formed to embed the inner layer circuit pattern.

14. The method of claim 8, wherein in the preparing of the carrier substrate, a carrier metal layer and a barrier metal layer are stacked on a carrier core and the carrier substrate having the barrier metal layer formed at an outermost layer thereof is prepared.

15. The method of claim 14, wherein in the preparing of the carrier substrate, the barrier metal layer and the carrier metal layer are made of different materials.

16. The method of claim 15, wherein in the preparing of the carrier substrate, the barrier metal layer is made of a material which does not react to an etchant removing the carrier metal layer.

17. The method of claim 15, wherein the barrier metal layer is made of titanium (Ti) or nickel (Ni).

18. The method of claim 14, wherein the removing of the carrier substrate includes:
separating the carrier core from the carrier metal layer;
removing the carrier metal layer with an etchant to which the carrier metal layer reacts; and
removing the barrier metal layer with an etchant to which the barrier metal layer reacts.
